(19) United States
(12) Patent Application Publication
(10) Pub. No.: US 2024/0333167 A1
(43) Pub. Date: Oct. 3, 2024

(54) POWER CONVERSION DEVICE, STRUCTURE OF POWER CONVERSION DEVICE, AND METHOD OF MANUFACTURING POWER CONVERSION DEVICE

(71) Applicant: Panasonic Intellectual Property Management Co., Ltd., Osaka (JP)

(72) Inventor: Shigeru NAKABAYASHI, Kanagawa (JP)

(21) Appl. No.: 18/420,469

(22) Filed: Jan. 23, 2024

(30) Foreign Application Priority Data
Mar. 28, 2023 (JP) 2023-051004

(51) Int. Cl. H02M 7/00; H05K 7/20

(52) U.S. Cl. CPC H02M 7/003; H05K 7/209

(57) ABSTRACT

A power conversion device includes a housing, a circuit board coupled to the housing, an electronic component including lead wires, and a heat radiation plate. The heat radiation plate supports a heat radiation face of the electronic component by a first face of the heat radiation plate in a heat exchangeable manner. The heat radiation face is disposed to face the first face. The heat radiation plate includes concave parts provided on a second face of the heat radiation plate in a position of facing the lead wires. The second face intersects with the first face. The concave parts dent toward a third face of the heat radiation plate. The third face is located on an opposite side of the second face. The third face intersects with the first face. The heat radiation plate is coupled to the housing on the third face in the heat exchangeable manner.

### CROSS-REFERENCE TO RELATED APPLICATIONS

This application is based upon and claims the benefit of priority from Japanese Patent Application No. 2023-051004, filed on Mar. 28, 2023, the entire contents of which are incorporated herein by reference.

### FIELD

The present disclosure relates generally to a power conversion device, a structure of the power conversion device, and a method of manufacturing the power conversion device.

### BACKGROUND

Conventionally, it has been requested that power conversion devices such as chargers mounted in electric vehicles or the like be reduced in size due to, for example, limitation on a mounting space.

For example, a patent literature JP 2017-108007 A discloses a technique for employing a structure in which an assembly, which is obtained by fixing a heat generating electronic component onto a side face of a heat sink with a spring, is fixed to a housing, longitudinally disposing the heat generating electronic component relative to the housing, and achieving reduction in size.

However, in a case where a circuit board is incorporated after the assembly of the heat sink and the heat generating electronic component has been fixed to the housing, a process is required to perform solder connection for joining the heat generating electronic component and a terminal of the circuit board in a state where the circuit board has been incorporated into the housing. Therefore, there is a problem that manufacturing processes become complicated.

### SUMMARY

A power conversion device according to the present disclosure includes a housing, a circuit board, an electronic component, and a heat radiation plate. The housing is integrally molded into a box shape. The circuit board is coupled to the housing. The electronic component includes lead wires being soldered and joined to the circuit board. The electronic component generates heat by energization from the circuit board via the lead wires. The heat radiation plate supports a heat radiation face of the electronic component by a first face of the heat radiation plate in a heat exchangeable manner. The heat radiation face of the electronic component is disposed to face the first face. The heat radiation plate includes concave parts provided on a second face of the heat radiation plate in a position of facing the lead wires of the electronic component. The second face intersects with the first face. The concave parts dent toward a third face of the heat radiation plate. The third face is located on an opposite side of the second face. The third face intersects with the first face. The heat radiation plate is coupled to the housing on the third face in the heat exchangeable manner.

### BRIEF DESCRIPTION OF THE DRAWINGS

FIG. 1 is a perspective view illustrating an example of a configuration of a power conversion device according to an embodiment;

FIG. 2 is a perspective view illustrating an example of the configuration of the power conversion device according to the embodiment;

FIG. 3 is a front view illustrating an example of the configuration of the power conversion device according to the embodiment;

FIG. 4 is a sectional view illustrating an example of the configuration of the power conversion device according to the embodiment; and

FIG. 5 is a perspective view illustrating an example of a configuration of a power conversion device according to a variation.

### DETAILED DESCRIPTION

An embodiment of a power conversion device, a structure of the power conversion device, and a method of manufacturing the power conversion device according to the present disclosure will be described below with reference to the drawings.

Note that in the description of the present disclosure, a component that has the same or roughly the same function as a function of a component described with reference to an already described drawing is denoted by the same reference sign, and description is appropriately omitted in some cases.

Moreover, even in a case where the same or roughly the same part is indicated, the part is indicated to have dimensions or a ratio that changes depending on the drawings in some cases. Moreover, for example, from the viewpoint of securing visibility of the drawings, in the description of each of the drawings, only principal components are denoted by reference signs, and even a component that has the same or roughly the same function as a function of a component described with reference to an already described drawing is not denoted by a reference sign in some cases.

Furthermore, a component that has the same or roughly the same function as a function of a component described with reference to an already described drawing is distinguished by adding an alphanumeric character at the end of a reference sign in some cases. Alternatively, in a case where components having the same or roughly the same function are not distinguished from each other, those components are described in an integrated manner by omitting the alphanumeric character added at the end of the reference sign.

### Embodiment

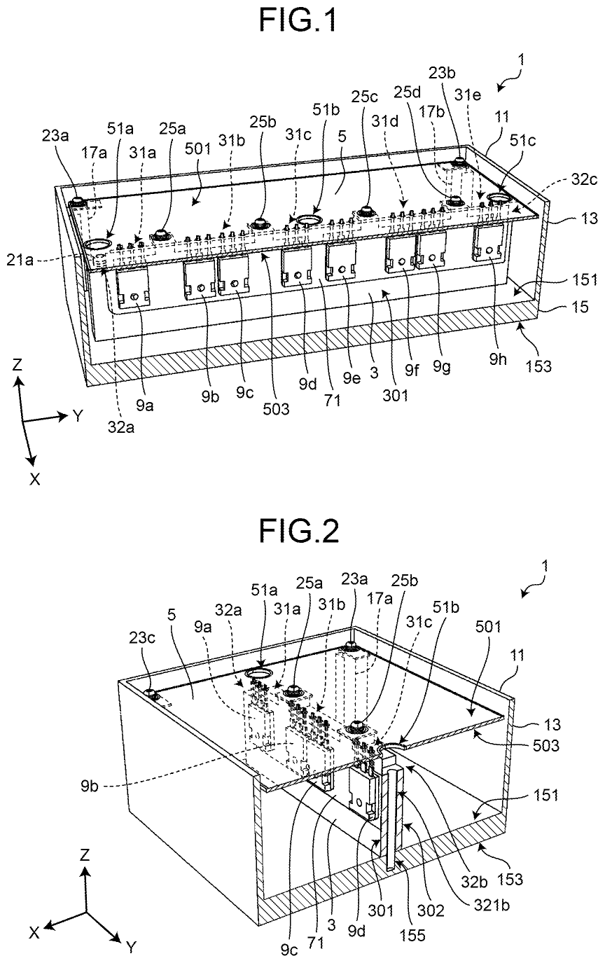

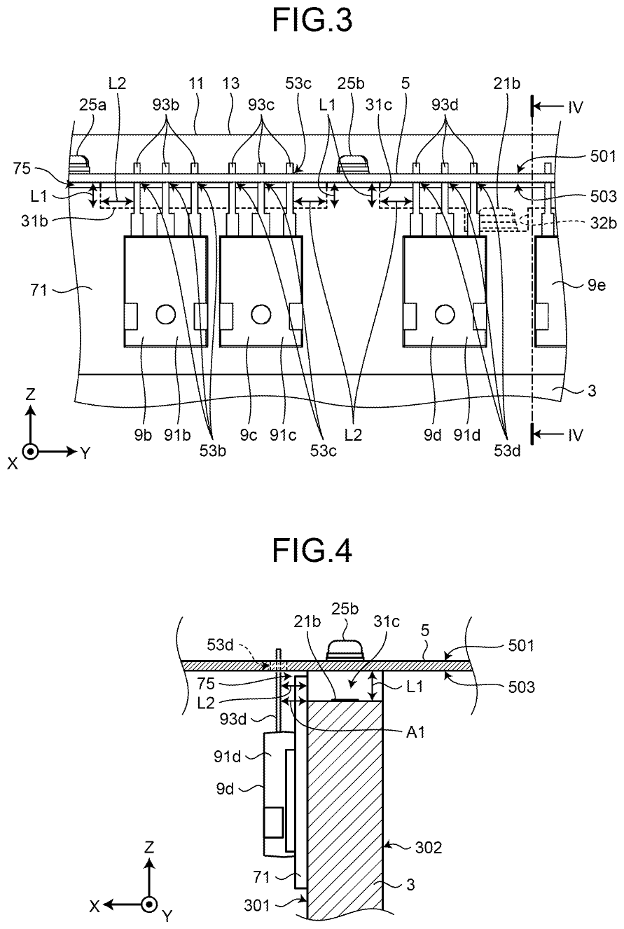

First, a configuration example of a power conversion device 1 according to the present embodiment will be described with reference to FIGS. 1 to 4. FIG. 1 is a perspective view illustrating an example of a configuration of the power conversion device 1 according to the embodiment. FIG. 1 illustrates a longitudinal section (a Y-Z plane). FIG. 2 is a perspective view illustrating an example of the configuration of the power conversion device 1 according to the embodiment. FIG. 2 illustrates a transverse section (a Z-X plane). FIG. 3 is a front view illustrating an example of the configuration of the power conversion device 1 according to the embodiment. Note that in FIG. 3, the illustration of a part on a front side (a +X side) of a side face 13 of a housing 11 is omitted. FIG. 4 is a sectional view illustrating an example of the configuration of the power conversion device 1 according to the embodiment. FIG. 4 illustrates a transverse section indicating a position of IV-IV in FIG. 3 when viewed in an arrow direction (the Z-X plane viewed from a +Y side). Note that in FIG. 4, the illustration of a part on a left-hand side (a −Y side) of the side face 13 of the housing 11 is omitted.

In one example, the power conversion device 1 according to the embodiment is an onboard charger that is mounted in an electric vehicle or the like. The onboard charger converts AC power supplied from a power source such as an external power source into DC power having a predetermined voltage, and outputs the DC power after conversion to a battery such as a lithium-ion battery.

The power conversion device 1 according to the embodiment is formed by, for example, coupling multiple parts, such as an electronic component, a circuit board, and a board unit, by using a fitting member such as a connector, a coupler, a screw, or a bolt, solder, an adhesive, or the like. Note that, in the power conversion device 1 according to the embodiment, not all the parts may be coupled, and some parts can be electrically connected or thermally connected by bringing the parts into contact with each other. Moreover, some parts that are coupled to each other or are in contact with each other may be insulated or thermally insulated from each other.

Note that the multiple parts are not limited to the above ones, and may include a terminal part used for electrical connection, such as a connector or a coupler, a cooling part, or the like. As the cooling part, various heat radiation mechanisms such as a heat sink, a heat diffusion plate, a heat radiation sheet, a heat radiation gap filler, or a heat pipe can be appropriately used. In one example, on an outer surface 153 of a bottom face 15 of the housing 11, the heat sink may be disposed in a heat exchangeable manner.

The power conversion device 1 according to the embodiment includes the housing 11, a heat radiation plate 3, a circuit board 5, an adhesive insulation sheet 71, and electronic components 9.

The housing 11 is integrally molded into, for example, a box shape, and is provided with an opening on only one face (a face on a +Z side). Note that, when assembling the housing 11, the side face 13 and the bottom face 15 of the housing 11 may be separately formed and may be coupled to each other.

On an inner surface 151 of the bottom face 15 of the housing 11, supports 17 (or bosses) are provided in a direction perpendicular to the bottom face 15 (a Z-direction). In one example, the supports 17 include supports 17a to 17c and 17d (not illustrated), which are provided at four corners of the bottom face 15. In each of the supports 17, a screw hole (not illustrated) is formed, and the circuit board 5 is screwed (fastened).

The heat radiation plate 3 is a member that is formed into a roughly rectangular parallelepiped shape such as a flat plate shape. The heat radiation plate 3 is formed of a material having thermal conductivity. In one example, the heat radiation plate 3 is formed of an aluminum alloy or a copper alloy. The heat radiation plate 3 is disposed inside the housing 11 in such a way that a shorter-side direction of the heat radiation plate 3 extends in a vertical direction (the Z-direction) of the housing 11. The heat radiation plate 3 that is disposed inside the housing 11 is coupled to the inner surface 151 of the bottom face 15 of the housing 11 in such a way that heat can be exchanged on an end face on one side in a shorter-side direction (a face on a −Z side) of the heat radiation plate 3. The heat radiation plate 3 supports a heat radiation face (a face on a −X side) of the electronic component 9 that is disposed to face a first side face 301 in such a way that heat can be exchanged by the first side face 301. The heat radiation plate 3 is a part configured to transport heat generated in the electronic component 9 to the housing and radiate heat. Here, the first side face 301 of the heat radiation plate 3 is an example of a first face. Moreover, an end face on one side in the shorter-side direction (a face on a +Z side) of the heat radiation plate 3, the end face intersecting with the first side face 301, is an example of a second face. Moreover, an end face on one side in the shorter-side direction (a face on the −Z side) of the heat radiation plate 3, the end face intersecting with the first side face 301 and being coupled to the housing 11, is an example of a third face.

Note that FIGS. 1 and 2 each illustrate a case where a single heat radiation plate 3 is provided. Alternatively, plural (two or more) heat radiation plates 3 may be provided inside the housing 11 together with the electronic components 9. Moreover, a shape of the heat radiation plate 3 is not limited to the flat plate shape. The heat radiation plate 3 may be formed into an L-shape, an angular U-shape (a one-end opened square shape), an angular O-shape (a square shape), an X-shape (a cross shape), or a polygonal shape, or a part or the entirety of the heat radiation plate 3 may have curvature like a cylinder. Moreover, the heat radiation plate 3 may include an extended part that extends from at least one of the first side face 301 and a second side face 302, for example, along an X-Y plane or in a direction that corresponds to the X-Y plane.

On a face on one side in the shorter-side direction (the +Z side) of the heat radiation plate 3, two or more first concave parts 31 are formed. The number, sizes, and positions of first concave parts 31 are determined in accordance with the number and positions of electronic components 9 attached to the heat radiation plate 3, as described later. In FIG. 1, the heat radiation plate 3 is provided with first concave parts 31a to 31e to form a plurality of concavities. On a face on one side in the shorter-side direction (the +Z side) of the heat radiation plate 3, in each of non-concave parts (convex parts) where the first concave part 31 is not formed, for example, between the first concave parts 31, a screw hole (not illustrated) is formed, and the circuit board 5 is screwed.

Although details of the concavities will be described later, a second concave part 32 being a concavity having a concave shape that dents in the same direction (toward the −Z side) is further formed in some of the first concave parts 31. In FIG. 1, second concave parts 32a and 32c are provided in the first concave parts 31a and 31e, respectively. In FIGS. 2 and 3, a second concave part 32b is provided in the first concave part 31c. Each of the second concave parts 32a to 32c is provided with a hole. In FIG. 2, a hole 321b is provided in the second concave part 32b. On the inner surface 151 of the bottom face 15 of the housing 11, holes are provided in a contract region with the heat radiation plate 3, and in the present embodiment, in positions that correspond to the holes provided in the respective second concave parts 32a to 32c. In FIG. 2, a hole 155 is spatially connected to the hole 321b provided in the second concave part 32b in a state where the heat radiation plate 3 is disposed in the housing 11, and into which a screw is inserted. In each of these holes of the bottom face 15, a screw hole (not illustrated) is formed, and the heat radiation plate 3 is screwed. This causes the heat radiation plate 3 to come into contact with the bottom face 15 on a face on one side in the shorter-side direction (the −Z side) of the heat radiation plate 3, and be fixed to the housing 11 in a heat exchangeable manner.

The circuit board 5 is, for example, a printed circuit board (PCB). In one example, the printed circuit board is a glass epoxy board formed by using an aluminum alloy or a copper alloy as a base material. On at least one principal surface of the circuit board 5, a pattern (not illustrated) is formed, or a predetermined electronic component (not illustrated) is mounted, and therefore a predetermined circuit configuration is provided. Here, a first surface 501, which is one principal surface of the circuit board 5, is a face (a face on the +Z side) that forms, for example, an outer surface on an upper side (the +Z side) of the power conversion device 1, and faces the same direction as an opening of the housing 11 in an assembled state. Moreover, a second surface 503, which is another principal surface, is a face (a face on the −Z side) that faces the first concave parts 31 of the heat radiation plate 3 in an assembled state.

Note that the circuit board 5 according to the embodiment may be an optional one of circuit boards that are coupled to each other as a board unit. The circuit board 5 according to the embodiment may be a circuit board included in a component of a magnetic material, that is, a magnetic component, such as a transformer, a reactor, or a choke. This magnetic component may include, for example, a board in which a conductor pattern forms winding, and a magnetic core may penetrate on an inside and an outside of the winding formed in the board to form a closed magnetic circuit, and therefore this magnetic component may have a function as a magnetic component.

The circuit board 5 is coupled to the housing 11. Therefore, in the circuit board 5, a hole (not illustrated) is provided in a position corresponding to each of the supports 17 of the housing 11. In a state where the circuit board 5 is placed on the supports 17 of the housing 11, the circuit board 5 is screwed and fixed to the supports 17 by screws 23 that are inserted in the holes corresponding to the supports 17. FIG. 1 illustrates screwed sections using screws 23a and 23b inserted in holes corresponding to the supports 17a and 17b. FIG. 2 illustrates a screwed section using each of the screw 23a and a screw 23c inserted in a hole corresponding to the support 17c.

Moreover, the circuit board 5 is coupled to the heat radiation plate 3. Specifically, the circuit board 5 is coupled to the non-concave parts (convex parts) each located between first concave parts 31 of the heat radiation plate 3, namely, in a place where the first concave part 31 is not provided. Therefore, in the circuit board 5, a hole (not illustrated) is provided in positions that correspond to the non-concave parts (convex parts). The circuit board 5 is screwed and fixed to the heat radiation plate 3 by screws 25 inserted in holes that correspond to the convex parts. FIGS. 1, 2, and 3 illustrate a screwed section using a screw 25a inserted in a hole that corresponds to a non-concave part between the first concave parts 31a and 31b. FIGS. 1 to 4 illustrate a screwed section using a screw 25b inserted in a hole that corresponds to a non-concave part between the first concave parts 31b and 31c. FIG. 1 illustrates a screwed section using each of a screw 25c inserted in a hole that corresponds to a non-concave part between the first concave parts 31c and 31d and a screw 25d inserted in a hole that corresponds to a non-concave part between the first concave parts 31d and 31e.

Moreover, the heat radiation plate 3 is coupled to the housing 11. Therefore, in the circuit board 5, a hole 51 is provided in a position that corresponds to each of the second concave parts 32 of the heat radiation plate 3, and specifically, the holes of the second concave parts 32. The holes 51 are formed so as to allow a tool of screwing, such as a screw driver, to be inserted in the holes 51. Screws 21, which are inserted in the holes provided in the second concave parts 32 of the heat radiation plate 3, are rotated by a tool inserted through the holes of the circuit board 5, and are screwed to the screw holes of the bottom face 15 of the housing 11. Thereby, the heat radiation plate 3 is screwed to the housing 11. FIG. 1 illustrates holes 51a to 51c that are provided in positions that correspond to the second concave parts 32a to 32c of the heat radiation plate 3. FIG. 1 also illustrates a screwed section where a screw 21a is used to screw the heat radiation plate 3 to the housing 11 by using the hole 51a. FIG. 2 illustrates the holes 51a and 51b, and a screwed section where a screw 21b is used to screw the heat radiation plate 3 to the housing 11 by using the hole 51b.

Moreover, lead wires 93 of the electronic component 9 are electrically connected to the circuit board 5. Therefore, in the circuit board 5, holes 53 are provided in positions that correspond to the lead wires 93 of the electronic component 9. In a state where the circuit board 5 is screwed to the heat radiation plate 3 to which the electronic component 9 is attached, the lead wires 93 can protrude from the holes 53 of the circuit board 5. Each of the lead wires 93 is electrically connected to a predetermined circuit configuration such as a pattern (not illustrated) formed in the circuit board 5 or a predetermined electronic component (not illustrated) by, for example, soldering. In one example, parts of the lead wires 93, which protrude from the holes 53 of the circuit board 5, are soldered and joined with the predetermined circuit configuration provided on the first surface 501 of the circuit board 5. FIG. 3 illustrates holes 53b to 53d that are provided in positions corresponding to lead wires 93b to 93d of electronic components 9b to 9d. FIG. 4 illustrates the hole 53d that is provided in the position corresponding to the lead wires 93d of the electronic component 9d.

The electronic component 9 includes a body 91 (in FIG. 3, respective bodies 91b, 91c, and 91d of the electronic components 9b, 9c, and 9d are illustrated), and lead wires 93 that extends from the body 91. The lead wires 93 are soldered and joined, for example, to be electrically connected to the predetermined circuit configuration provided in the circuit board 5. The lead wires 93 are disposed in a position that faces the first concave part 31 of the heat radiation plate 3, for example, to be close to the first concave part 31. The electronic component 9 is an electronic component that self-heats by energization from the circuit board 5 via the lead wires 93. The electronic component 9 is provided with a heat radiation face (a face on the −X side). Alternatively, an optional face in an outer surface of the electronic component 9 is handled as the heat radiation face.

The electronic component 9 is a discrete part or a module, and is, for example, a semiconductor element such as a field effect transistor (FET), a semiconductor module, a magnetic material, or a part such as a condenser and a breaker. The semiconductor module is constituted by, for example, multiple semiconductor elements. The magnetic material refers to a transformer integrated printed board, a transformer, a reactor, or a choke. The breaker is a relay or a fuse. In the present embodiment, the FET is described as an example of the electronic component 9. In the present embodiment, electronic components 9a to 9h are described as an example of the electronic component 9. Note that the number of electronic components 9 or a type of the electronic component 9 is optionally determined, and can be appropriately designed.

The electronic components 9 are attached to the heat radiation plate 3 in such a way that the heat radiation face of each of the electronic components 9 faces the first side face 301 of the heat radiation plate 3, and comes into thermal contact with the first side face 301 through the adhesive insulation sheet 71. The electronic component 9 fixed to the heat radiation plate 3 enters an erect state in the vertical direction (the Z-direction), and the electronic component 9 is separated from the housing 11, and does not come into contact with the housing 11. Note that the electronic component 9 does not necessarily need to be provided on the first side face 301, and may be provided on the second side face 302.

The adhesive insulation sheet 71 has insulation properties, thermal conductivity, and adhesiveness, and is, for example, a double-sided tape formed into a sheet shape. The adhesive insulation sheet 71 is disposed between the first side face 301 of the heat radiation plate 3 and the heat radiation face (the face on the −X side) of the electronic component 9. The adhesive insulation sheet 71 is stuck on the first side face of the heat radiation plate 3 by adhesive force of the adhesive insulation sheet 71, and supports the electronic component 9 on a face on an opposite side (the +X side) of the heat radiation plate 3 by the adhesive force of the adhesive insulation sheet 71. In other words, the adhesive insulation sheet 71 fixes the heat radiation face of the electronic component 9 to the first side face 301 of the heat radiation plate 3. The adhesive insulation sheet 71 is in thermal contact with each of the heat radiation plate 3 and the electronic component 9, and serves as a heat conducting member that transports heat generated in the electronic component 9 to the heat radiation plate 3. Here, the adhesive insulation sheet 71 is an example of an insulation member.

As described above, the power conversion device 1 according to the present embodiment has a structure that the heat radiation plate 3 attached to the electronic component 9 through the adhesive insulation sheet 71 is thermally connected to the housing 11. With this structure, heat generated in the electronic component 9 is transported via the adhesive insulation sheet 71 and the heat radiation plate 3 to the housing 11. Therefore, heat radiation of the electronic component 9 can be achieved.

Moreover, the power conversion device 1 according to the present embodiment has a structure that the heat radiation plate 3, which is in thermal contact with the housing 11 that can exchange heat with an outside, supports the heat radiation face of the electronic component 9 in a heat exchangeable manner. Therefore, the heat radiation of the electronic component 9 can be handled while preventing an increase in size in comparison with a structure that the heat radiation face of the electronic component 9 is disposed to be in direct contact with the bottom face 15 of the housing 11.

Details of the first concave parts 31 that are provided on a face on one side in the shorter-side direction (the +Z side) of the heat radiation plate 3 will be described.

Each of the first concave parts 31 is provided in a position that faces the lead wires 93 of the electronic component 9 on an end face on one side in the shorter-side direction (a face on the +Z side) of the heat radiation plate 3. Each of the first concave parts 31 has a concave shape over the first side face 301 and the second side face 302. The concave shape is a shape that dents from a face on one side (the +Z side) toward a face on another side (the −Z side) in the shorter-side direction of the heat radiation plate 3. In other words, a face on one side in the shorter-side direction (the +Z side) of the heat radiation plate 3 is provided with convex parts (non-concave parts) each being formed into a protruding shape that protrudes to a side (the +Z side) opposite to a face on another side in the shorter-side direction (the −Z side) of the heat radiation plate 3, that is, a side closer to the circuit board 5, from the first side face 301 to the second side face 302. The convex parts support the circuit board 5 together with the supports 17, and are screwed to the circuit board 5 by the screws 25.

In the present disclosure, it is assumed that a width of each of the first concave parts 31 refers to a length between the first side face 301 and the second side face 302 of the heat radiation plate 3 (in an X-direction). Moreover, it is assumed that a length of each of the first concave parts 31 refers to the longer-side direction (a Y-direction) of the heat radiation plate 3, that is, a direction in which the electronic components 9 are arranged in the heat radiation plate 3. Additionally, it is assumed that a depth of each of the first concave parts 31 refers to a length from an end face on one side in the shorter-side direction (the +Z side) of the heat radiation plate 3, that is, protruding faces of the non-concave parts.

It is sufficient that the number of first concave parts 31 is determined on the basis of, for example, the number of non-concave parts serving as a screwed section of the heat radiation plate 3 and the circuit board 5.

It is sufficient that a size and a position of each of the first concave parts 31 is determined on the basis of, for example, a size of the heat radiation plate 3 or a position of the electronic component 9 that is disposed on a side face of the heat radiation plate 3.

Specifically, the depth of the first concave parts 31 is specified by an insulation distance L1 that corresponds to a potential difference between the heat radiation plate 3 and the circuit board 5 in order to secure insulation between a predetermined circuit configuration provided on the second surface 503 of the circuit board 5 and the heat radiation plate 3, as illustrated in FIGS. 3 and 4. For example, the depth of each of the first concave parts 31 is greater than or equal to the insulation distance L1. In other words, a bottom face (a face on the −Z side) of each of the first concave parts 31 is separated from the second surface 503 of the circuit board 5 by the insulation distance L1 or more. It is sufficient that the insulation distance L1 is appropriately determined in accordance with an operating voltage of the predetermined circuit configuration, or the like.

Moreover, a depth of the second concave part 32 that is provided in some first concave parts 31 of the first concave parts 31 is specified by the insulation distance L1 for securing insulation between a screw head (an end on the +Z side) of the screw 21 that is inserted in the hole of the second concave part 32 to fasten the heat radiation plate 3 to the housing 11, and the predetermined circuit configuration provided on the second surface 503 of the circuit board 5. For example, a length between the screw head of the screw 21 and the predetermined circuit configuration provided on the second surface 503 of the circuit board 5 is greater than or equal to the insulation distance L1. Note that the screw head of the screw 21 may protrude or may not protrude from the second concave part 32, that is, a bottom face (a face on the −Z side) of the first concave part 31.

Moreover, a length of each of the first concave parts 31 is specified by an insulation distance L2 that corresponds to a potential difference between the heat radiation plate 3 and the lead wires 93 in order to secure insulation between the lead wires 93 of at least one electronic component 9 provided in a corresponding position and the heat radiation plate 3, as illustrated in FIGS. 3 and 4. Note that the insulation distance L2 is, for example, a distance on an end face in the shorter-side direction (an X-Y plane) of the heat radiation plate 3, but is dividedly illustrated in FIGS. 3 and 4 for the sake of a paper space. For example, a length of the first concave part 31b is determined in such a way that a distance between the lead wires 93b of the electronic component 9b and the lead wires 93c of the electronic component 9c is greater than or equal to the insulation distance L2. In other words, a side face (a Z-X plane) of each of the first concave parts 31 is separated from the lead wires 93 by the insulation distance L2 or more. Specifically, a face closer to the first concave part 31a (the Z-X plane on the −Y side) in the first concave part 31b and the lead wires 93b of the electronic component 9b are separated from each other by the insulation distance L2 or more, for example, on the X-Y plane. Similarly, a face closer to the first concave part 31c (the Z-X plane on the +Y side) in the first concave part 31b and the lead wires 93c of the electronic component 9c are separated from each other by the insulation distance L2 or more, for example, on the X-Y plane.

Moreover, a width of each of the first concave parts 31 is specified by a width (a length in the X-direction) of the heat radiation plate 3. Note that, in the heat radiation plate 3, a part that does not need to secure the insulation distance L1 from the predetermined circuit configuration provided on the second surface 503 of the circuit board 5 does not need to be formed in a concave shape. For example, on the second surface 503 of the circuit board 5, in a case where the predetermined circuit configuration is not provided in a region that faces a side closer to the second side face 302 (the −X side) in the heat radiation plate 3, the first concave part 31 may be only provided on a side closer to the first side face 301 (the +X side) of a face on one side in the shorter-side direction (the +Z side) of the heat radiation plate 3.

Note that insulation-coating may be applied to the first concave part 31 provided in the heat radiation plate 3. In this case, it is sufficient that a size of the concave shape is appropriately adjusted in accordance with insulation performance of the insulation-coating.

As described above, in the power conversion device 1 according to the present embodiment, the heat radiation plate 3 is provided with the concave shape in a part that faces a heat generating electronic component terminal to be attached, that is, the lead wires 93 of the electronic component 9. This enables the insulation distance L1 or L2 to be secured between the heat radiation plate 3 and the circuit board 5. Accordingly, by employing the configuration described above, a circuit configuration that is electrically connected to the lead wires 93 of the electronic component 9, that is, a circuit configuration having the same potential, can be disposed on the second surface 503 on a side closer to the heat radiation plate 3 of the circuit board 5. Therefore, by employing the configuration described above, a degree of freedom of design of a predetermined circuit configuration to be provided in the circuit board 5 can be improved, the mounting density of the circuit board 5 can be increased, and a size of the power conversion device 1 can be reduced.

Here, details of disposition of the adhesive insulation sheet 71 on the heat radiation plate 3 are described.

On the heat radiation plate 3, the adhesive insulation sheet 71 extends from a side closer to the bottom face 15 (the −Z side) below the heat radiation face of the electronic component 9 toward the circuit board 5 up to the first concave parts 31 along the first side face 301. In other words, the adhesive insulation sheet 71 is disposed to cover the concavities that are close to the lead wires 93 of the electronic component 9.

As described above, in the power conversion device 1 according to the present embodiment, the adhesive insulation sheet 71 for fixing the electronic component 9 to the heat radiation plate 3 is disposed to cover the first concave part 31 of the heat radiation plate 3. This enables insulation to be secured between the bottom face (a face on the −Z side) of the first concave part 31 of the heat radiation plate 3 and the heat generating electronic component terminal, that is, the lead wires 93 of the electronic component 9 (arrow A1). Accordingly, by employing the configuration described above, a distance between the heat radiation plate 3 and the electronic component 9 can be reduced, and thus a size of the power conversion device 1 can be reduced.

Note that there is no need to insulate, from the heat radiation plate 3, a circuit configuration that is provided on the second surface 503 of the circuit board 5, and has the same potential as that of the lead wires 93 of the electronic component 9 by electrical connection. Therefore, a clearance 75 may be provided between the adhesive insulation sheet 71 and an end face on one side in the shorter-side direction (the +Z side) of the heat radiation plate 3, that is, the second surface 503 of the circuit board 5. In other words, it is sufficient that the adhesive insulation sheet 71 and the second surface 503 of the circuit board 5 are separated from each other by the clearance 75, and the adhesive insulation sheet 71 and the second surface 503 do not necessarily need to be in contact with each other. This configuration can avoid interference between the circuit configuration provided on the second surface 503 of the circuit board 5 and the adhesive insulation sheet 71, and therefore damage to the circuit configuration can be reduced, a degree of freedom of design can be improved, and mounting density can be increased.

Next, a method for manufacturing the power conversion device 1 according to the embodiment will be described with reference to FIGS. 1 to 4. The power conversion device 1 according to the embodiment has the configuration described above, so that the power conversion device 1 can be manufactured by performing the processes described below.

First, the heat radiation plate 3 in which the first concave parts 31 are formed on an end face on one side in the shorter-side direction (the +Z side) is prepared. In the heat radiation plate 3, the first concave parts 31 may be formed by removing part of a plate-shaped member having a flat plate shape, or may be formed by coupling members that constitute the non-concave parts (convex parts) described above to the plate-shaped member having the flat plate shape. Note that the heat radiation plate 3 may be formed in processes of the present manufacturing method, or may be formed in a process of another method performed prior to the processes of the present manufacturing method.

Next, the adhesive insulation sheet 71 is used to fix and bond the electronic components 9 to the first side face 301 of the heat radiation plate 3 in which the first concave parts 31 have been formed. In this case, the electronic components 9 are disposed in positions that correspond to the first concave parts 31. The heat radiation faces of the electronic components 9 face the first side face 301 of the heat radiation plate 3 through the adhesive insulation sheet 71.

Subsequently, the circuit board 5 is screwed, by using the screws 25, to the first side face 301 of the heat radiation plate 3 to which the electronic components 9 have been fixed. In the processes of manufacturing the power conversion device 1 according to the present embodiment, the circuit board 5 is screwed to the heat radiation plate 3 in a state where the circuit board 5 has not yet been screwed to the supports 17 of the housing 11, namely, a state where the heat radiation plate 3 is not disposed in the housing 11.

Next, soldering is performed to join the lead wires 93 of the electronic components 9, which have been fixed to the heat radiation plate 3, to the circuit board 5, which has been fixed to the same heat radiation plate 3. In the processes of manufacturing the power conversion device 1 according to the present embodiment, the electronic components 9 are soldered onto the circuit board 5 in a state where the circuit board 5 has not yet been screwed to the supports 17 of the housing 11, that is, a state where the heat radiation plate 3 is not disposed in the housing 11.

Next, the heat radiation plate 3 and the electronic components 9 that have been integrally coupled are housed inside the housing 11 through the opening (the +Z side) of the housing 11. In this case, an end face on a side opposite to the circuit board 5 in the shorter-side direction (a face on the −Z side) of the heat radiation plate 3 is supported by the bottom face 15 of the housing 11. Moreover, the circuit board 5 is supported by each of the supports 17 of the housing 11 and the non-concave parts (the convex parts) where the first concave part 31 of the heat radiation plate 3 is not provided. Then, the heat radiation plate 3 is screwed to the housing 11 by using the screws 21, and the circuit board 5 is screwed to the supports 17 by using the screws 23. Then, the heat radiation plate 3 and the circuit board 5 that are in an integrally coupled state are screwed and fixed to the housing 11.

The power conversion device 1 illustrated in FIGS. 1 to 4 is manufactured by the manufacturing method described above.

Variation in dimensions of components may occur in, for example, the process of forming the housing 11 or the heat radiation plate 3. In this case, if a height (a length in the Z-direction) varies among the supports 17, or among the convex parts of the heat radiation plate 3, or among the supports 17 and the convex parts, there is a possibility that a soldered and joined part will be destroyed by stress, for example, such that the circuit board 5 fixed to the housing 11 warps. Therefore, soldering and joining needs to be performed after the heat radiation plate 3 and the circuit board 5 are installed in the housing 11. Moreover, in the power conversion device 1 after manufacturing, in a case where component dimensions or a shape changes due to an influence of external environment such as ambient temperature, there is also a possibility that the soldered and joined part will be destroyed by stress.

In contrast, according to the manufacturing method of the present embodiment described above, in the process of incorporating the integrally coupled heat radiation plate 3 and electronic components 9 into the housing 11, the circuit board 5 has been screwed to the heat radiation plate 3 to which the electronic components 9 are already fixed, and the electronic components 9 have been soldered and joined to the circuit board 5. Accordingly, in this process, members to be soldered and joined have been fixed to each other. Therefore, soldering and joining are not needed after the heat radiation plate 3 and the circuit board 5 have been mounted in the housing 11, and the manufacturing process can be prevented from becoming complicated. Moreover, the heat radiation plate 3 and the circuit board 5 have been screwed, and therefore generation of stress in a soldered and joined part due to variations in component dimensions or an influence of external environment can be mitigated.

### Variation

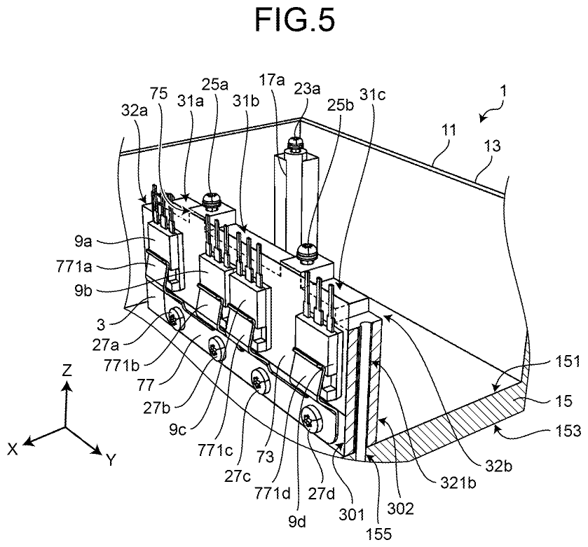

A configuration example of a power conversion device 1 according to the present variation will be described with reference to FIG. 5. FIG. 5 is a perspective view illustrating an example of a configuration of a power conversion device 1 according to the variation. Note that, in FIG. 5, the illustration of the circuit board 5 is omitted.

The power conversion device 1 according to the present variation has the same configuration as a configuration of the power conversion device 1 according to the embodiment illustrated in FIGS. 1 to 4 with the exception that an insulation sheet 73 is used in place of the adhesive insulation sheet 71 and a flat spring 77 (an example of a spring member) is further provided, as illustrated in FIG. 5.

The insulation sheet 73 is similar to the adhesive insulation sheet 71 with the exception of lack of adhesiveness. The insulation sheet 73 is an example of the insulation member.

The flat spring 77 is disposed on the same plane (the first side face 301) as a plane of the electronic components 9 on the heat radiation plate 3. The flat spring 77 is screwed and fixed to the first side face 301 of the heat radiation plate 3 by using screws 27a to 27d. The flat spring 77 includes a presser 771. In the flat spring 77, the presser 771 comes into contact with a face on a side opposite to the heat radiation face of the electronic component 9 (a face on the +X side) in a state where the flat spring 77 is fixed to the first side face 301, and therefore the flat spring 77 biases the electronic component 9 and the insulation sheet 73 toward the heat radiation plate 3. As illustrated in FIG. 5, the flat spring 77 includes pressers 771a to 771d. The flat spring 77 is configured to bias the electronic components 9a to 9d and the insulation sheet 73 by the pressers 771a to 771d so as to push and fix the electronic components 9a to 9d and the insulation sheet 73 onto the heat radiation plate 3. Note that the flat spring 77 may be provided for each electronic component 9, or may be provided for each of the electronic components 9.

In a method for manufacturing the power conversion device 1 according to the present variation, the electronic components 9 are fixed, by using the flat spring 77, to the first side face 301 of the heat radiation plate 3, in which the first concave parts 31 are formed, through the insulation sheet 73. In this structure, the heat radiation faces of the electronic components 9 face the first side face 301 of the heat radiation plate 3 through the insulation sheet 73. Note that, in the power conversion device 1 according to the present variation, the adhesive insulation sheet 71 may be used similarly to the embodiment described above.

By employing the above-described configuration, effects that are similar to effects of the embodiment described above can be exhibited.

Note that, in the power conversion device 1 described above, inside the heat radiation plate 3, a space having a roughly rectangular parallelepiped shape may be provided, and another electronic component such as a reactor may be disposed in the space. In this case, a potting material may be provided between the electronic component and the heat radiation plate 3 in the above-described space to fill a gap between them.

Note that, in the power conversion device 1 described above, it is sufficient that parts such as the heat radiation plate 3 and the circuit board 5 are coupled to each other at a requested intensity, and a method of the coupling is not limited to screwing, and may be implemented by a latch structure or an adhesive, or may be implemented by a combination thereof.

At least one embodiment described above can prevent manufacturing processes from becoming complicated by a reduction in size of a power conversion device.

While certain embodiments have been described, these embodiments have been presented by way of example only, and are not intended to limit the scope of the inventions. Indeed, the novel methods and systems described herein may be embodied in a variety of other forms; moreover, various omissions, substitutions and changes in the form of the methods and systems described herein may be made without departing from the spirit of the inventions. The accompanying claims and their equivalents are intended to cover such forms or modifications as would fall within the scope and spirit of the inventions.

### (Supplementary Notes)

The description of the embodiment described above discloses the technique described below.

### (Supplementary Note 1)

A power conversion device or a structure of a power conversion device comprising:

a housing that is integrally molded into a box shape;

a circuit board that is coupled to the housing;

an electronic component that includes lead wires being soldered and joined to the circuit board, the electronic component generating heat by energization from the circuit board via the lead wires; and

a heat radiation plate that supports a heat radiation face of the electronic component by a first face of the heat radiation plate in a heat exchangeable manner, the heat radiation face of the electronic component being disposed to face the first face, the heat radiation plate including concave parts provided on a second face of the heat radiation plate in a position of facing the lead wires of the electronic component, the second face intersecting with the first face, the concave parts denting toward a third face of the heat radiation plate, the third face being located on an opposite side of the second face and intersecting with the first face, the heat radiation plate being coupled to the housing on the third face in the heat exchangeable manner.

### (Supplementary Note 2)

The power conversion device or the structure of a power conversion device according to the supplementary note 1, further comprising an insulation member that has insulation properties and thermal conductivity, the insulation member being disposed between the first face of the heat radiation plate and the heat radiation face of the electronic component, the insulation member extending from a side closer to the third face than the heat radiation face toward the second face along the first face to cover the concave parts.

### (Supplementary Note 3)

The power conversion device or the structure of a power conversion device according to the supplementary note 2, wherein the insulation member further has adhesiveness to fix the heat radiation face of the electronic component to the first face of the heat radiation plate.

### (Supplementary Note 4)

The power conversion device or the structure of a power conversion device according to the supplementary note 2, further comprising a spring member that is fixed to the first face of the heat radiation plate, the spring member coming into contact with a face on a side opposite to the heat radiation face of the electronic component to bias the electronic component and the insulation member toward the heat radiation plate.

### (Supplementary Note 5)

The power conversion device or the structure of a power conversion device according to any one of the supplementary notes 1 to 4, wherein the circuit board is coupled to a non-concave part of the second face of the heat radiation plate, the non-concave part being part where the concave parts are not provided.

### (Supplementary Note 6)

The power conversion device or the structure of a power conversion device according to any one of the supplementary notes 1 to 5, wherein the concave parts each have a bottom face being separated from the circuit board by a first insulation distance or more, the first insulation distance corresponding to a potential difference between the heat radiation plate and the circuit board.

### (Supplementary Note 7)

The power conversion device or the structure of a power conversion device according to any one of the supplementary notes 1 to 6, wherein the concave parts each have a side face being separated from the lead wires by a second insulation distance or more, the second insulation distance corresponding to a potential difference between the heat radiation plate and the lead wires.

### (Supplementary Note 8)

A method of manufacturing a power conversion device, the method comprising:

fixing an electronic component to a heat radiation plate in a heat exchangeable manner, the electronic component generating heat by energization from a circuit board via lead wires of the electronic component, the fixing of the electronic component to the heat radiation plate including
disposing a first face of the heat radiation plate to face a heat radiation face of the electronic component, and
disposing the lead wires of the electronic component to face concave parts provided on a second face intersecting with the first face of the heat radiation plate, the concave parts denting toward a third face of the heat radiation plate, the third face being located on an opposite side of the second face and intersecting with the first face;

fixing the circuit board to the second face of the heat radiation plate to which the electronic component has been fixed;

soldering and joining the circuit board and the lead wires of the electronic component having been fixed to the heat radiation plate; and

housing, inside a housing integrally molded into a box shape, the heat radiation plate to which the electronic component and the circuit board have been fixed, fixing the third face of the heat radiation plate to the housing in the heat exchangeable manner, and fixing the circuit board to the housing.

What is claimed is:

1. A power conversion device comprising:
a housing that is integrally molded into a box shape;
a circuit board that is coupled to the housing;
an electronic component that includes lead wires being soldered and joined to the circuit board, the electronic component generating heat by energization from the circuit board via the lead wires; and
a heat radiation plate that supports a heat radiation face of the electronic component by a first face of the heat radiation plate in a heat exchangeable manner, the heat radiation face of the electronic component being disposed to face the first face, the heat radiation plate including concave parts provided on a second face of the heat radiation plate in a position of facing the lead wires of the electronic component, the second face intersecting with the first face, the concave parts denting toward a third face of the heat radiation plate, the third face being located on an opposite side of the second face and intersecting with the first face, the heat radiation plate being coupled to the housing on the third face in the heat exchangeable manner.

2. The power conversion device according to claim 1, further comprising an insulation member that has insulation properties and thermal conductivity, the insulation member being disposed between the first face of the heat radiation plate and the heat radiation face of the electronic component, the insulation member extending from a side closer to the third face than the heat radiation face toward the second face along the first face to cover the concave parts.

3. The power conversion device according to claim 2, wherein the insulation member further has adhesiveness to fix the heat radiation face of the electronic component to the first face of the heat radiation plate.

4. The power conversion device according to claim 2, further comprising a spring member that is fixed to the first face of the heat radiation plate, the spring member coming into contact with a face on a side opposite to the heat radiation face of the electronic component to bias the electronic component and the insulation member toward the heat radiation plate.

5. The power conversion device according to claim 1, wherein the circuit board is coupled to a non-concave part of the second face of the heat radiation plate, the non-concave part being part where the concave parts are not provided.

6. The power conversion device according to claim 1, wherein the concave parts each have a bottom face being separated from the circuit board by a first insulation distance or more, the first insulation distance corresponding to a potential difference between the heat radiation plate and the circuit board.

7. The power conversion device according to claim 1, wherein the concave parts each have a side face being separated from the lead wires by a second insulation distance or more, the second insulation distance corresponding to a potential difference between the heat radiation plate and the lead wires.

8. A structure of a power conversion device, the structure comprising:
a housing that is integrally molded into a box shape;
a circuit board that is coupled to the housing;
an electronic component that includes lead wires being soldered and joined to the circuit board, the electronic component generating heat by energization from the circuit board via the lead wires; and
a heat radiation plate that supports a heat radiation face of the electronic component by a first face of the heat radiation plate in a heat exchangeable manner, the heat radiation face of the electronic component being disposed to face the first face, the heat radiation plate including concave parts provided on a second face of the heat radiation plate in a position of facing the lead wires of the electronic component, the second face intersecting with the first face, the concave parts denting toward a third face of the heat radiation plate, the third face being located on an opposite side of the second face and intersecting with the first face, the heat radiation plate being coupled to the housing on the third face in the heat exchangeable manner.

9. A method of manufacturing a power conversion device, the method comprising:
fixing an electronic component to a heat radiation plate in a heat exchangeable manner, the electronic component generating heat by energization from a circuit board via lead wires of the electronic component, the fixing of the electronic component to the heat radiation plate including
disposing a first face of the heat radiation plate to face a heat radiation face of the electronic component, and
disposing the lead wires of the electronic component to face concave parts provided on a second face intersecting with the first face of the heat radiation plate, the concave parts denting toward a third face of the heat radiation plate, the third face being located on an opposite side of the second face and intersecting with the first face;
fixing the circuit board to the second face of the heat radiation plate to which the electronic component has been fixed;
soldering and joining the circuit board and the lead wires of the electronic component having been fixed to the heat radiation plate; and
housing, inside a housing integrally molded into a box shape, the heat radiation plate to which the electronic component and the circuit board have been fixed, fixing the third face of the heat radiation plate to the housing in the heat exchangeable manner, and fixing the circuit board to the housing.
